(19) United States
(12) Patent Application Publication
(10) Pub. No.: US 2015/0115132 A1
(43) Pub. Date: Apr. 30, 2015

(54) VISIBLE AND NEAR INFRA RED OPTICAL SENSOR

(71) Applicant: ISRAEL HIRSCH, Hertzilia (IL)

(72) Inventor: Israel Hirsch, Hertzilia (IL)

(21) Appl. No.: 14/407,680

(22) PCT Filed: Jun. 5, 2013
(86) PCT No.: PCT/IL2013/050483

§ 371 Date: Dec. 12, 2014

(30) Foreign Application Priority Data
Jun. 13, 2012 (IL) 220392

(51) Int. Cl. H01L 31/0304; H01L 31/101; H01L 27/146

(52) U.S. Cl. CPC H01L 31/0304; H01L 27/14636; H01L 31/03046; H01L 31/1013
USPC 250/208.1; 250/216; 257/184

(57) ABSTRACT

A detector for detecting visible and NIR electromagnetic radiation is disclosed. The aforesaid detector comprises: (a) a substrate made of conventional temperature grown semi-insulating gallium arsenide (GaAs); (b) an active layer; and (c) means for applying electric fields to the active layer. The active layer is made of low temperature grown semi-insulating GaAs or made of ion implanted conventional temperature grown semi insulating GaAs. Also disclosed an imager based on monolithically integrated array of detectors and read-out integrated circuit (ROIC).

### FIELD OF THE INVENTION

The present invention generally relates to a GaAs based high speed photo detector sensitive in visible and near-infrared spectral range. More specifically, the present invention relates to a photo detector provided with a semi insulating active layer of low temperature grown GaAs or ion implanted GaAs.

### BACKGROUND OF THE INVENTION

U.S. Pat. No. 7,705,415 ('415) discloses a device for detecting electromagnetic radiation, charged particles or photons including a 2-dimensional electron gas (2 DEG) and/or a 2-dimensional hole gas (2 DHG). The device detects the collective response of the plasma to perturbations of the 2 DEG and/or the 2 DHG. The device is tunable by using Schottky contacts. The device can be used for high-speed photo detector devices, terahertz sensors, and charged particle sensors.

“Enhanced long wavelength response in a GaAs photodetector” by Nakajima, Kazutoshi Sugimoto et al. (Appl. Phys. Lett., 1992, Vol. 61, No. 21, pp. 2575-2576), discloses a metal-semiconductor-metal photo detector (MSM-PD) fabricated on a semi-insulating GaAs which has a long wavelength response beyond the energy gap. It is enhanced by applying a second bias voltage to the bottom electrode. When the bias is 100 V, the responsivity exceeds the unit quantum efficiency, which indicates that a photoconductive amplification function exists. Since the dark current is as small as 0.2 nano amperes, it may be more suitable than an InGaAs or a Ge photodiode for long wavelength detection. The physical origin seems different from that in the typical short wavelength range, since the frequency response is rather slow.

The schematic MSM-PD structure, fabricated on a semi-insulating (SI) GaAs. The Schottky metal is TiPtAu, directly deposited on SI GaAs. The chip area is (1.3×0.9) mm² with 0.45 mm thickness, and the photosensitive area is (0.2×0.2) mm², with interdigital electrodes of 5 μm finger and spacing widths. An anti-reflection coating of SiN film is deposited thereon. The chip is assembled on a metal package using a conductive resin, which acts as an ohmic contact, so that a second bias voltage can be applied to the bottom of the chip. This bias sets up a vertical electric field.

According to U.S. Pat. No. 4,158,851, in a semi-insulating gallium arsenide single crystal containing at least one of deep acceptor impurities and at least one of deep donor impurities and having a resistivity of at least about 10^{6′} Ω·cm at 300° K. (1) at least one of the deep donor impurities is oxygen, the oxygen concentration in the single crystal being at least about 4·10¹⁶ cm⁻³, while the silicon concentration in the single crystal being simultaneously at most about 2·10¹⁵ cm⁻³, (2) at least one of the deep acceptor impurities is chromium, the chromium concentration in the single crystal being within a range of about 3·10¹⁵ cm⁻³, to about 3·10¹⁷ cm⁻³ and (3) at least one of tellurium, tin, selenium and sulphur is contained as another shallow donor impurity than silicon so to satisfy the relationship of N_{AA}>N_{D}−N_{A}>N_{DD} wherein N_{AA} represents the sum of concentrations of the deep acceptor impurities including chromium, N_{DD} represents the sum of concentrations of the deep donor impurities including oxygen, N_{D} represents the sum of concentrations of the shallow donor impurities including electrically active lattice defects and N_{A} represents the sum of concentrations of the shallow acceptor impurities including electrically active lattice defects.

U.S. Pat. No. 5,051,804 disclose a photo detector having an advantageous combination of sensitivity and speed; it has a high sensitivity while retaining high speed. In a preferred embodiment, visible light is detected, but in some embodiments, x-rays can be detected, and in other embodiments infrared can be detected. The present invention comprises a photo detector having an active layer, and a recombination layer. The active layer has a surface exposed to light to be detected, and comprises a semiconductor, having a band gap graded so that carriers formed due to interaction of the active layer with the incident radiation tend to be swept away from the exposed surface. The graded semiconductor material in the active layer preferably comprises Al₁₋ₓGaₓAs. An additional sub-layer of graded In_{1-y}Ga_{y}As may be included between the Al₁₋ₓGaₓAs layer and the recombination layer. The recombination layer comprises a semiconductor material having a short recombination time such as a defective GaAs layer grown in a low temperature process. The recombination layer is positioned adjacent to the active layer so that carriers from the active layer tend to be swept into the recombination layer. In an embodiment, the photo detector may comprise one or more additional layers stacked below the active and recombination layers. These additional layers may include another active layer and another recombination layer to absorb radiation not absorbed while passing through the first layers. A photo detector having a stacked configuration may have enhanced sensitivity and responsiveness at selected wavelengths such as infrared.

There is a long-felt and unmet need to provide a non-expensive high speed photo detector responsive for both visible and/or extended NIR spectral bands with a voltage controlled responsivity and detecting spectral band.

### SUMMARY OF THE INVENTION

It is hence one object of the invention to provide a detector for detecting visible and NIR electromagnetic radiation, said detector comprising: (a) a substrate made of semi-insulating gallium arsenide (GaAs); (b) an active layer; and (c) means for applying electric fields to said active layer.

It is a core purpose of the invention to provide the active layer made of low-temperature grown GaAs.

It is another core purpose of the invention to provide the active layer made of ion implanted GaAs.

It is a further object of the invention to provide the active layer doped with an impurity selected from the group consisting of chromium, ferrum, oxygen and any combination thereof.

It is a further object of the invention to provide the active layer which is annealed.

It is a further object of the invention to provide a buffer layer of an undoped GaAs sandwiched between said substrate and back gate conducting layer.

It is a further object of the invention to provide an etch stop layer of AlₓGa₍₁₋ₓ₎As or InₓGa₍₁₋ₓ₎P sandwiched between said back gate and active layer, where 0.10<x<0.90.

It is a further object of the invention to provide the means for applying electric fields oriented horizontally and/or vertically to said active layer.

It is a further object of the invention to provide the means for applying said vertical electric field comprising a back gate conducting layer electrode made of substantially doped GaAs layer or substantially doped AlₓGa₍₁₋ₓ₎As layer, where 0.10<x<0.90, with a contact configured for applying said vertical field.

It is a further object of the invention to provide the means for applying said vertical electric field comprising AlGaAs—GaAs heterojunction, further wherein a supply layer of AlₓGa₍₁₋ₓ₎As n-type uniformly doped or n-type delta (δ) doped, is coated onto a spacer layer of undoped AlₓGa₍₁₋ₓ₎As formed on said active layer, where 0.10<x<0.90 results in an accumulated sheet

[symbol]

It is a further object of the invention to provide the means for applying said vertical electric field comprising AlGaAs—InGaAs—GaAs heterojunction. A supply layer of AlₓGa₍₁₋ₓ₎As n-type uniformly doped or n-type delta (δ) doped, coated onto a spacer layer of undoped AlₓGa₍₁₋ₓ₎As followed by an undoped InₓGa₍₁₋ₓ₎As channel layer formed on said active layer, where 0.10<x<0.90 results in an accumulated sheet of electrons (2 DEG) in the channel layer.

It is a further object of the invention to provide the means for applying a magnetic field to said active layer.

It is a further object of the invention to provide the means for applying said electric field to said active layer comprising at least one Schottky contact.

It is a further object of the invention to provide the means for applying said electric field to said active layer comprising at least one ohmic contact.

It is a further object of the invention to provide the contacts optically transparent in the visual and NIR spectral bands in a substantial manner.

It is a further object of the invention to provide the detector configured for front illumination.

It is a further object of the invention to provide the detector configured for back illumination.

It is a further object of the invention to provide an imager for imaging in the visible and NIR spectral bands. The aforesaid imager comprises: (a) a monolithically integrated array of detectors comprising (i) an array shared substrate made of semi-insulating gallium arsenide (GaAs); (ii) an array shared buffer layer made of semi insulating GaAs; (iii) a shared array means for applying vertical electrical fields to said active layer; (iv) a shared array etch stop layer; (v) a shared array active layer; (vi) means for applying horizontal electric field to said active layer individually to each elemental detector; (vii) reading means electrically connected to each elemental detector in an individual manner (b) a read-out integrated circuit (ROIC) for individually interrogating each detector in said array, controlling array's operation and processing the detected signals from each detectors of said array to create a combined video signal; and (c) means for electrically connecting each detector of said array to said ROTC.

It is a further object of the invention to provide a shared array of InGaAs channel layer

[symbol]

It is a further object of the invention to provide the array with imaging means.

It is a further object of the invention to provide the imaging means selected from the group consisting of a lens and a microlens array.

It is a further object of the invention to provide a method for detecting electromagnetic radiation comprising the steps of: (a) providing detector for detecting visible and NIR electromagnetic radiation, said detector comprising: (i) a substrate made of semi-insulating gallium arsenide (GaAs); (ii) an active layer; (iii) means for applying electric fields to said active layer; (b) illuminating said detector by electromagnetic radiation; and (c) measuring change in current across means for applying an electric field;

It is a further object of the invention to provide a method for imaging in electromagnetic radiation comprising the steps of: (a) providing an imager for imaging in the visible and NIR spectral bands, said imager based on an array of the above described comprising: (i) a monolithically integrated array of detectors comprising (1) a shared array substrate made of semi-insulating gallium arsenide (GaAs); (2) a shared array buffer layer made of semi insulating GaAs; (3) a shared array means for applying vertical electrical fields to said active layer; (4) a shared array etch stop layer; (5) an array shared active layer or a shared array of InGaAs channel layer followed by said shared array active layer; (6) means for applying a horizontal electric field to said active layer individually to each elemental detector; (7) reading means electrically connected to each elemental detector in an individual manner (ii) a read-out integrated circuit (ROIC) for individually interrogating each detector in said array, controlling array's operation and processing the detected signals from each detectors of said array to create a combined video signal; (iii) means for electrically connecting each detector of said array to said ROIC; (b) illuminating said detector by electromagnetic radiation; and (c) measuring change in current across means for applying an electric field;

### BRIEF DESCRIPTION OF THE DRAWINGS

In order to understand the invention and to see how it may be implemented in practice, a plurality of embodiments is adapted to now be described, by way of non-limiting example only, with reference to the accompanying drawings, in which

FIGS. 1 to 5 illustrate different embodiments of sensor sandwich structure;

FIGS. 6 to 8 show an exemplary elemental pixel configuration of a sensor array;

FIG. 9 shows a two dimensional (2D) array of pixel detectors;

FIG. 10 shows an imager configured as a hybrid integration of a two dimensional (2D) array of pixel detectors and a Silicon based read-out integrated circuit (ROIC); and

FIG. 11 is an enlarged view of the indium bumps used in the hybrid integration shown in FIG. 10.

### DETAILED DESCRIPTION OF THE INVENTION

The following description is provided, so as to enable any person skilled in the art to make use of said invention and sets forth the best modes contemplated by the inventor of carrying out this invention. Various modifications, however, are adapted to remain apparent to those skilled in the art, since the generic principles of the present invention have been defined specifically to provide a sensor for detecting VISIBLE and/or NIR electromagnetic radiation and an array based thereof.

The term “conventional temperature grown (CTG) GaAs” hereinafter refers to a substrate of GaAs and/or crystal layer of GaAs grown at temperature around 600° C.

The term “low-temperature grown (LTG) GaAs” hereinafter refers to a crystal layer of GaAs grown at temperature below 600° C.

The term “ion implanted” hereinafter refers to Arsenide ion implanted CTG GaAs, or Oxygen ion implanted CTG GaAs, or Arsenide ion with Oxygen ion implanted CTG GaAs, or Oxygen ion implanted LTG GaAs.

The term “visible” spectral band hereinafter refers to a spectral interval from approximately 400 nm up to 870 nm corresponding to GaAs PD band to band photo excitation up to its cut off wavelength.

The term “near infra-red (NIR)” or “extended NIR” spectral band hereinafter refers to a spectral interval from 870 nm up to 2000 nm corresponding to GaAs sub band-gap photo excitation.

The term “etch stop” layer hereinafter refers to a layer of AlₓGa₍₁₋ₓ₎As or a layer of InₓGa₍₁₋ₓ₎P, where 0.10<x<0.90.

The term “supply layer of AlₓGa₍₁₋ₓ₎As n-type doped” hereinafter refers to a uniformly n-type doped AlₓGa₍₁₋ₓ₎layer or delta (δ) n-type doped AlₓGa₍₁₋ₓ₎As layer, where 0.10<x<0.90.

The term “back gate conductive” layer hereinafter refers to a substantially doped GaAs layer or to a substantially doped AlₓGa₍₁₋ₓ₎As layer, where 0.10<x<0.90.

The term “active layer” hereinafter refers to a GaAs layer. In case of AlGaAs—InGaAs—GaAs heterostructure, the aforesaid active layer refers to a GaAs layer coated on top with a channel layer of InₓGa₍₁₋ₓ₎As where 0.10<x<0.90.

The term “front illumination” hereinafter refers to illumination of a photo sensor from the side of the anode and cathode electrodes.

The term “back illumination” hereinafter refers to illumination of a photo sensor through the substrate. In the case when a substrate is thinned or entirely removed, the aforesaid term refers to the illumination of a photo sensor from a side of the back gate conducting layer thereof.

The term “horizontal electric field” refers hereinafter to an electric field distributed along the active layer due to the voltage applied across the anode and cathode electrodes (called metal electrodes or contacts—in case anode and cathode are directly coated on the active layer, and called anode and cathode layers—in case metal contacts are coated on the n-type doped anode layer and p-type doped cathode layer within the active layer) of the photo sensor.

The term “vertical electric field” refers hereinafter to an electric field distributed in the active layer (i) due to the voltage applied between the back gate electrode and the anode or cathode electrodes of the photo sensor and/or (ii) due to the electron accumulated sheet layer (2 DEG) between the anode and cathode electrodes in reference to the back gate electrode.

The band gap of the GaAs is about 1.43 eV. A CTG undoped semi insulating (SI) GaAs based photo sensor is very responsive to the visible range of electromagnetic spectrum up to its cut off wave length of 870 nm. This corresponds to the band-to-band photo excitation In the CTG undoped SI GaAs active layer there are also naturally formed (during the growing [symbol] from these levels to the conduction band. This corresponds to responsivity beyond the cut off wave length of 870 nm and called NIR responsivity. This NIR responsivity is extremely low (down to three orders of magnitude lower than the maximum visible responsivity), as the optical absorption in NIR is extremely low and as the defects act also as traps with high trapping cross section.

In the disclosed detector, we provide a GaAs based sensor with SI active layer with naturally formed (while layer growing and/or ion implanted) defects and metal precipitates. In the disclosed detector, if we additionally apply (additionally to the usual operating voltage applied between the anode and cathode) an intensive vertical electric field, as a result, the NIR responsivity is dramatically enhanced. In the prior art, the enhancement in NIR responsivity comes on account of detector's speed according the rule that gain-bandwidth product is constant. However, in the disclosed detector, the additionally applied vertical electric field enhances the entire gain-bandwidth product. Thus, a novel GaAs based NIR photo sensor is provided.

The aforesaid major defects in the GaAs active layer called EL2 are originated from defects appearing naturally in CTG process and significantly more massed EL2 like defects appearing in LTG process. In accordance with an alternative embodiment of the present invention, the active layer can be obtained also by means of Arsenide (As) ions bombardment of a CTG GaAs grown layer, or Oxygen ions bombardment of a CTG GaAs grown layer, or As ions with Oxygen ions bombardment of the CTG GaAs grown layer, or Oxygen ions bombardment of LTG GaAs layer. By the collision of an As ion beam with lattice atoms in the GaAs layer, vacancies, interstitials and antisites are formed. The dominant defects are Arsenide Gallium antisite (As_{Ga}) defects act as deep donors. If a GaAs layer is ion implanted, yielding a similar concentration of defects, we may expect same EL2 like defects appearing while bombarding and similar carrier-trapping mechanisms as in LTG GaAs layer. Both, LTG or As ion implantation create defects which are deep donor traps with energy level located around mid band-gap. Similarly, Oxygen ion implantation creates defects with energy levels partially located also around mid band-gap and act as deep acceptors. Similarly, As ion with Oxygen ion implantation (or Oxygen ion implantation of LTG GaAs layer) create deep donor and deep acceptor both with energy levels located around mid band-gap.

The LTG (or ion implanted) GaAs active layer should be highly resistive to minimize the [symbol] it can be achieved either through annealing that forms metal precipitates and/or through intentionally doping (for example, metal dopants such as Chromium and Ferrum) being deep acceptors as a compensation to the naturally formed deep donor. Such metal precipitates and/or metal dopants have energy levels located around mid-band-gap so that they may contribute to the NIR photo excitation through both: trap to conduction band photo emission and photoemission from the metal precipitates (and/or metal dopants and/or Schottky contacts in the depletion layer).

The disclosed detector has a LTG (or ion implanted) GaAs active layer made with relatively high concentration (#cm³) of defects and precipitates. Consequently, in an active layer of thickness of approximately 1 micrometer, the high concentration of defects and precipitates that act also as traps results in a very short life time of the photo carriers, so high speed of operation is realized. In the disclosed detector the around mid band gap defects and the metal precipitates act as the major source of NIR photo carriers. The NIR photo emissivity is: (i) linearly dependent on the ionized defects and the precipitates concentrations, and (ii) more strongly dependent on the additionally applied vertical electrical field. As a result, a room temperature low dark current and low cost GaAs based sensor with a practical and efficient capability to enhance NIR gain-bandwidth product is provided.

The aforesaid additionally applied vertical electrical field (additional to the horizontal electric field and additional to the back gate voltage originated vertical electric field) can be implemented also through an AlGaAs—GaAs heterostructure (or AlGaAs—InGaAs—GaAs pseudomorphic heterostructure) that forms a highly accumulated sheet of electrons (2 DEG) on the top of the GaAs active layer (or on top of the InGaAs channel layer in case of the pseudomorphic heterostructure). This highly accumulated sheet of electrons forms a locally intensive electrical field that vertically distributes along the GaAs active layer (or along the InGaAs channel layer and the GaAs active layer in case of the pseudomorphic heterostructure) toward the back gate electrode. As this electrical field is heterostructure epi layers originated its maximum intensity and its distribution are fixed after detector's fabrication. On the other hand the back gate electrode serves as an independent source of vertical electrical field. Its polarity and intensity affects the over whole field distribution within the active layer. As a result responsivity of the photo detector is controlled through the polarity and intensity of the voltage applied to the back gate contact. A back gate voltage that enhances significantly the responsivity in NIR spectral range actually extends the photo detector natural band to band responsivity, into the NIR spectrum beyond the band to band cut off wavelength. With a back gate voltage that does not enhance the NIR responsivity, the photo detector still keeps its high natural band to band responsivity.

Each photo sensor constitutes a sandwich structure comprising a semi-insulating GaAs substrate and the following layers thereon: a GaAs buffer layer, a back gate conducting (for example made of highly doped GaAs or AlGaAs) layer, etching stop layer (for example made of InGaP or AlGaAs), a highly resistive GaAs based active layer made of: LTG, or As ion implanted CTG GaAs, or Oxygen ion implanted CTG GaAs, or As ion with Oxygen ion implanted CTG GaAs, or Oxygen ion implanted LTG GaAs provided with interdigitated anode and cathode Schottky and/or Ohmic contacts and a heterostructure comprising of an AlGaAs n-type doped (uniformly doped or delta (δ) doped) supply layer followed by an undoped spacer layer of AlGaAs (or a spacer layer followed by an undoped channel layer of InGaAs) on the top of the GaAs based active layer between the anode and cathode contacts.

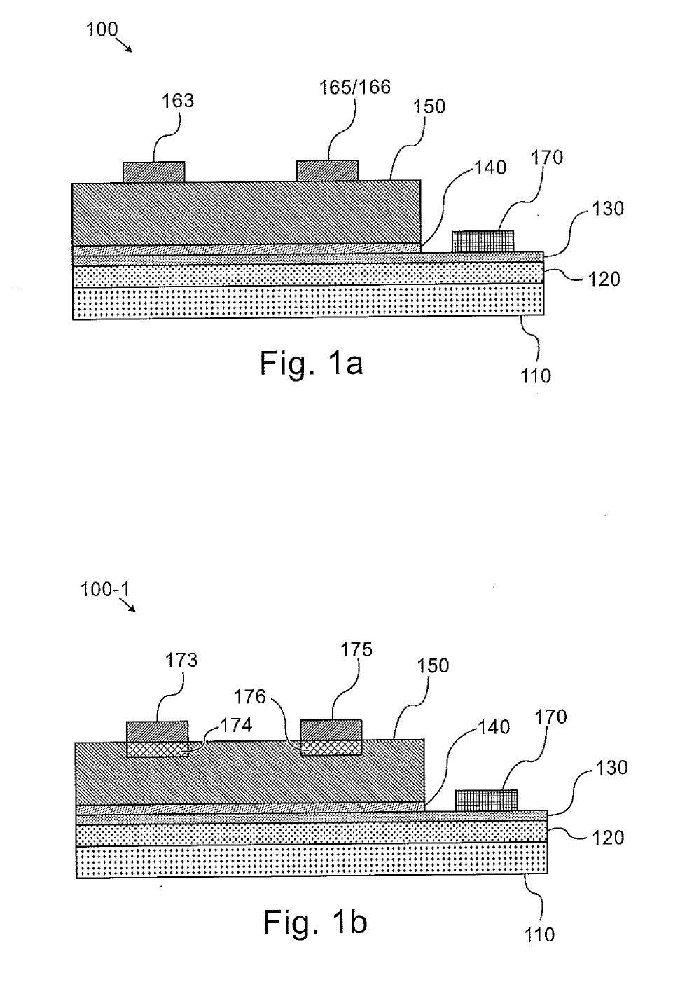

Reference is now made to FIG. 1a, presenting a schematic view (not to scale) of an exemplary sensor sandwich structure 100 constituting a metal-semiconductor-metal (MSM) photo detector. The aforesaid structure comprises a substrate 110 made of CTG unintentionally doped semi-insulating GaAs. The aforesaid substrate carries a buffer layer (typically thickness up to 1 μm) made of semi-insulating GaAs 120 and a typically thickness of 0.2 μm back gate conducting layer 130 made of doped GaAs (or doped AlGaAs or doped InGaP which in the same time act as etch stop layer as well) typically doped with Si 10¹⁸ cm⁻³. The back gate conducting layer 130 is provided with an ohmic contact 170 typically thickness of 500 \acute{Å}, AuGe (or AuGeNiAu or NiGeAu). In case of GaAs back gate conducting layer a typically thickness of 50 \acute{Å} etch stop layer 140 for example made of In_{0.48}Ga_{0.52}P or Al_{0.3}Ga_{0.7}As is interlaid between the layer 130 and a 1 μm to 3 μm thick active layer 150 of LTG (or ion implanted) highly resistive GaAs. The active layer 150 is provided with a pair of interdigitated Schottky contacts anode and cathode 163 and 165 of (typically thickness of 500 \acute{Å}, Ti/Pt/Au) or Schottky anode 163 and Ohmic cathode 166. The contacts can be of optically transparent to the detecting spectral bands such as Cadmium-Tin Oxide (CTO) or Indium-Tin Oxide (ITO). Electric voltage can be applied between the Schottky anode 163 and Schottky Ohmic cathode 165/166 so a horizontal called electrical field is distributed along the active layer 150. An additional electric voltage can be applied across Schottky contact- 163 and the back gate conducting layer electrode 130 through the ohmic contact 170.

In this case, an additional electrical field is vertically distributed along the active layer 150. It should be emphasized that optically transparent contacts are in the scope of the present invention.

Reference is now made to FIG. 1b, presenting an alternative exemplary embodiment of the present invention 100-1. The shown structure comprises ohmic contacts 173 and 175 which are in electric contact with doped areas 174 and 176 of N- and P-types, respectively within the layer 150. The shown arrangement is characterized by N-type semiconductor area 174, P-type 176 area and I-type (intrinsic) are disposed between N- and P-areas constitutes a lateral PIN Photodiode. The contacts can be of optically transparent to the detecting spectral bands such as CTO or ITO.

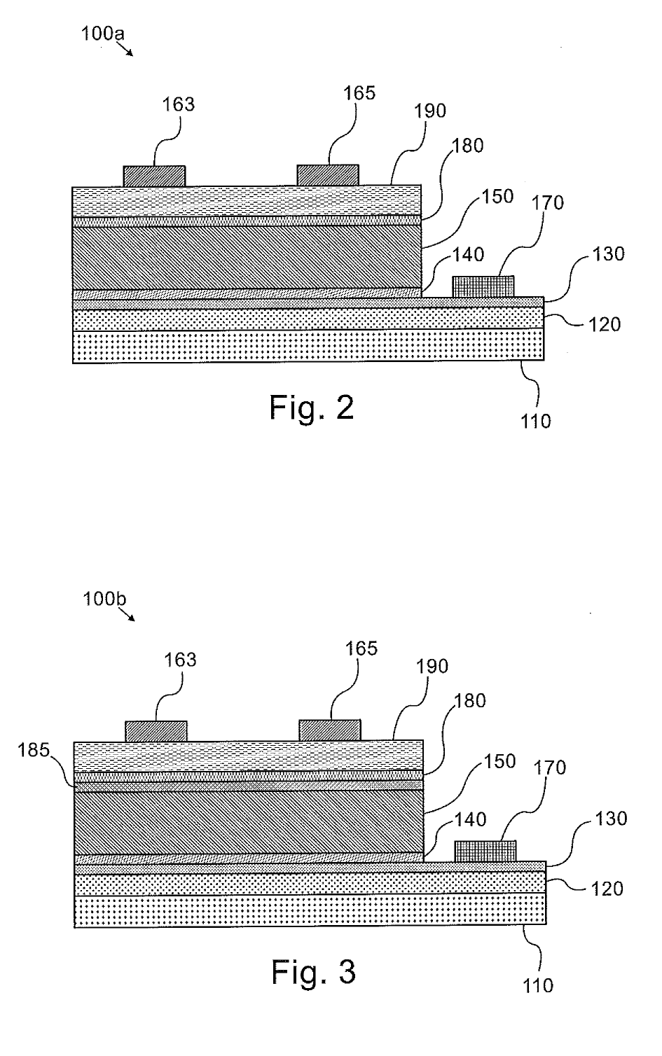

Reference is now made to FIG. 2, presenting another exemplary embodiment 100a of the sensor sandwich structure. The active layer 150 is covered with a typically thickness of 500 \acute{Å} layer called a supply layer 190 of uniformly doped n-type Al_{0.24}Ga_{0.76}As (for example doped with Si in a typical concentration of 5·10¹⁷ [#/cm³]) or delta (δ) doped n-type Al_{0.24}Ga_{07.6}As (typically with Si ˜5·10¹² #cm²). The abovementioned layer is spaced apart from active layer 150 by means of a ˜50 \acute{Å} undoped layer of Al_{0.24}Ga_{0.76}As called a spacer layer 180. These Al_{0.24}Ga_{07.6}As layers on the GaAs active layer 150 creates an AlGaAs—GaAs heterostructure and provides a classical Two Dimensional Electron Gas—2 DEG at the upper surface of the active layer between the Anode and Cathode Schottky contacts 163 and 165 of the photo sensor.

Reference is now made to FIG. 3, presenting a further exemplary embodiment 100b of the sensor sandwich structure. The active layer 150 is covered with a typically thickness of 500 \acute{Å} supply layer 190 of uniformly doped n-type Al_{0.24}Ga_{0.76}As (for example doped with Si in a typical concentration of 5·10¹⁷ [#cm³]) or delta (δ) doped n-type Al_{0.24}Ga_{0.76}As (typically with Si ˜5·10¹² #cm²). The abovementioned layer is spaced apart from active layer 150 by means of a ˜50 \acute{Å} undoped layer of Al_{0.24}Ga_{0.76}As called a spacer layer 180 followed by a typically thickness of 150 \acute{Å} layer of In_{0.15}Ga_{.085}As called channel layer 185. These layers on the GaAs active layer 150 creates an AlGaAs—InGaAs—GaAs pseudomorphic heterostructure and provides a classical Two Dimensional Electron Gas—2 DEG at the upper surface of the channel layer between the Anode and Cathode Schottky contacts 163 and 165 of the photo sensor.

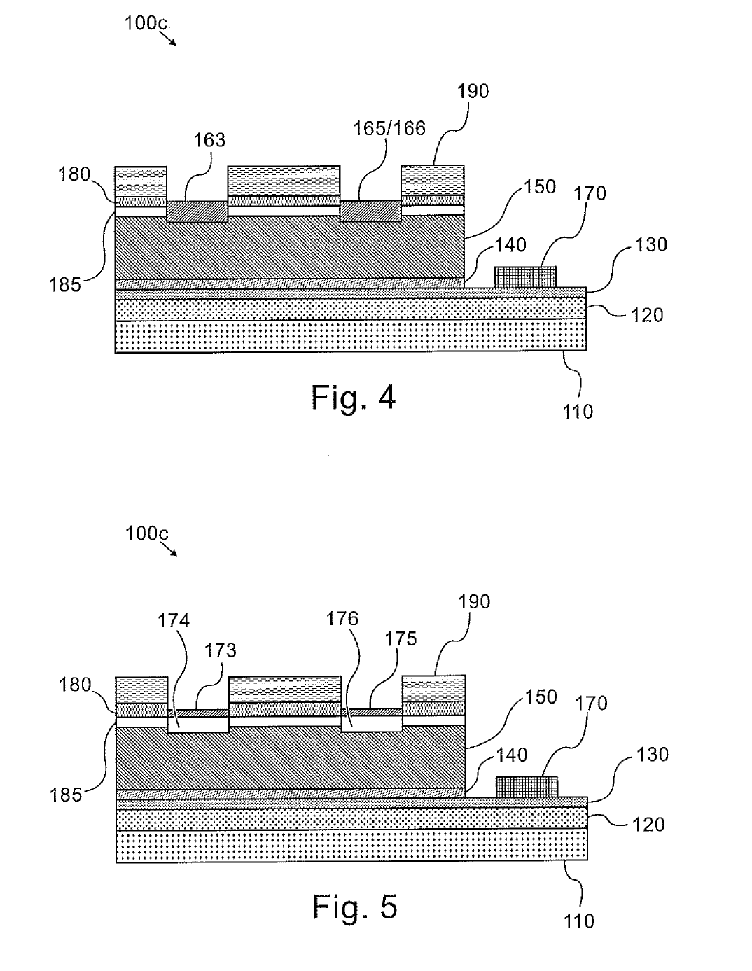

Reference is now made to FIG. 4, presenting a further exemplary embodiment 100c of the sensor sandwich structure in reference to FIG. 2 (or to FIG. 3). The embodiment 100c has the same sandwich structure as in FIG. 2 (or to FIG. 3) but characterized by buried Schottky anode 163 and Schottky ohmic cathode 165/166, respectively, which are in electric contact with the active layer 150 (or in electric contact with channel layer 185 and the active layer 150). It should be noted that contacts 163 and 165/166 are still in Schottky contact with spacer layer 180

Reference is now made to FIG. 5, presenting an alternative exemplary embodiment of the present invention 100c-1. The Schottky anode 163 and cathode 165 in the sandwich structure shown in FIG. 4 are replaced with contacts 173 and 175 which are in ohmic contact with doped areas 174 and 176 of N- and P-types, respectively. It should be noted that contacts 173 and 175 are still in Schottky contact with spacer layer 180. The shown arrangement is characterized by N-type semiconductor area 174, P-type 176 area and I-type (intrinsic) are disposed between N- and P-areas constitutes a lateral PIN Photodiode.

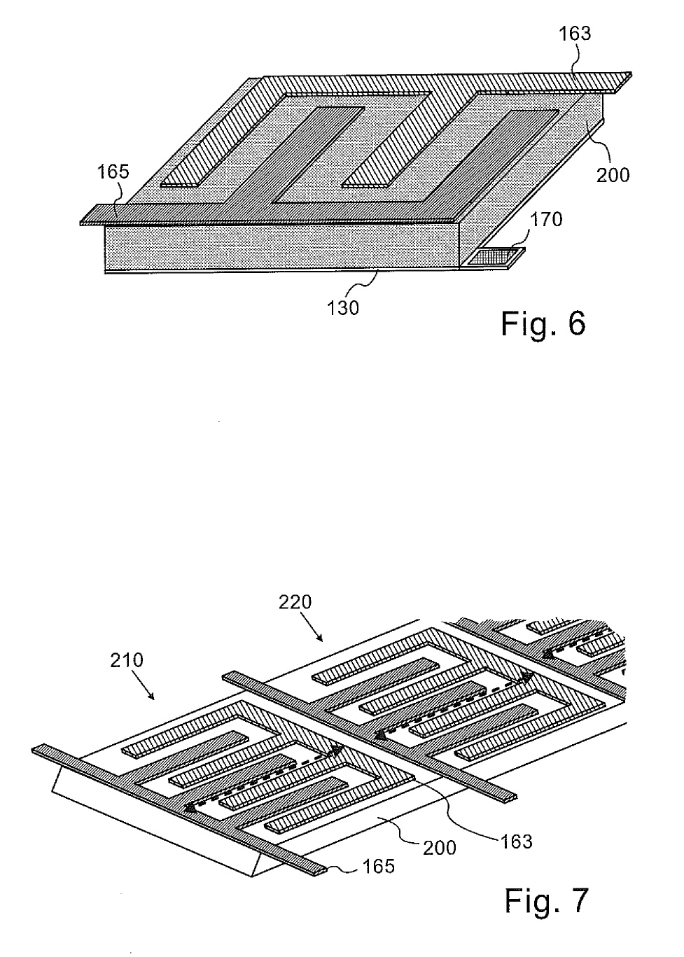

Reference is now made to FIG. 6, showing an exemplary elemental cell of a photo sensor array of the present invention. A sandwich structure 200 can include layers 140-150 and 180-190 (or 185-180-190) and layers 110 and 120 not shown. A cathode 165 and an anode 163 are attached to an upper face of the sandwich structure 200 while the ohmic contact 170 is electrically connected to the back gate 130. In accordance with the present invention, radiation to be detected can be incident to upper or bottom faces of the sandwich structure 200.

Reference is now made to FIG. 7, showing an exemplary photo sensor linear array. Numerals 210 and 220 refer to single cells of the photo sensor array and detect incident radiation in an independent manner. It should be emphasis that sandwich structure 200 and back gate layer 130 with its contact 170 (not shown) are common structure and layer to the entire array of photo sensors. However each photo sensor has its own anode and cathode contacts 165 and 163 respectively.

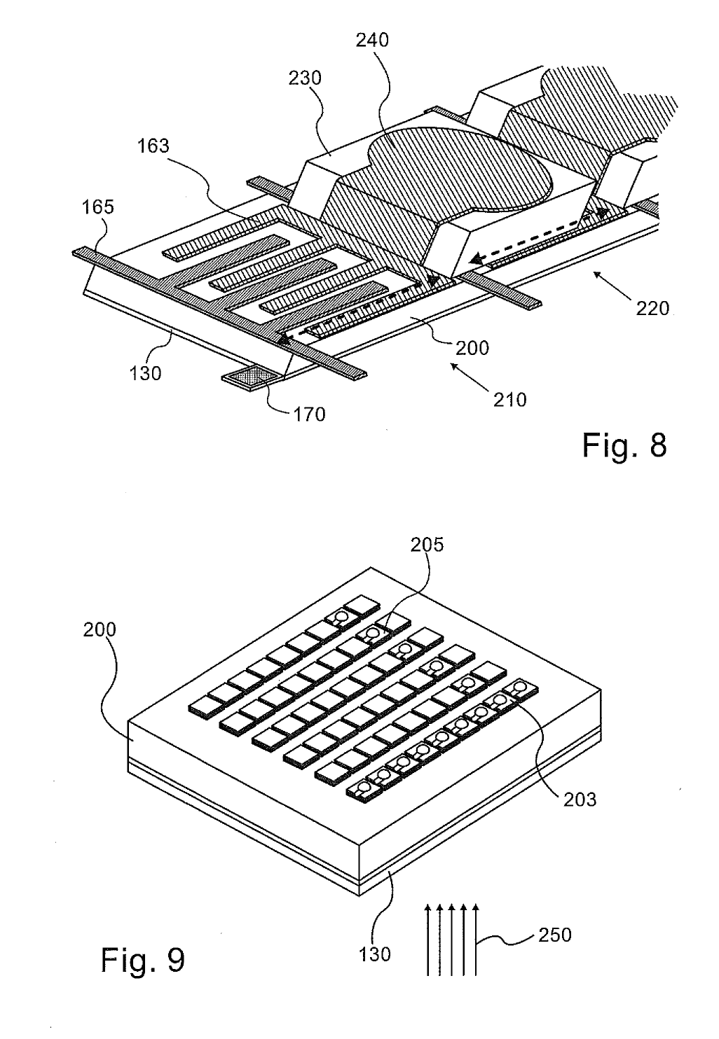

Reference is now made to FIG. 8, showing an exemplary structure providing separation of circuit pertaining to different photo sensor cells. Specifically, the anode 163 is electrically connected to a contact patch 240 (aimed to the Indium bump contact—not shown) bedding a plate 230 made, for example, of silicon nitrite. The aforesaid plate 230 provides electric insulation between the contact patch 240 of the cell 210 and MSM electrodes of the cell 220.

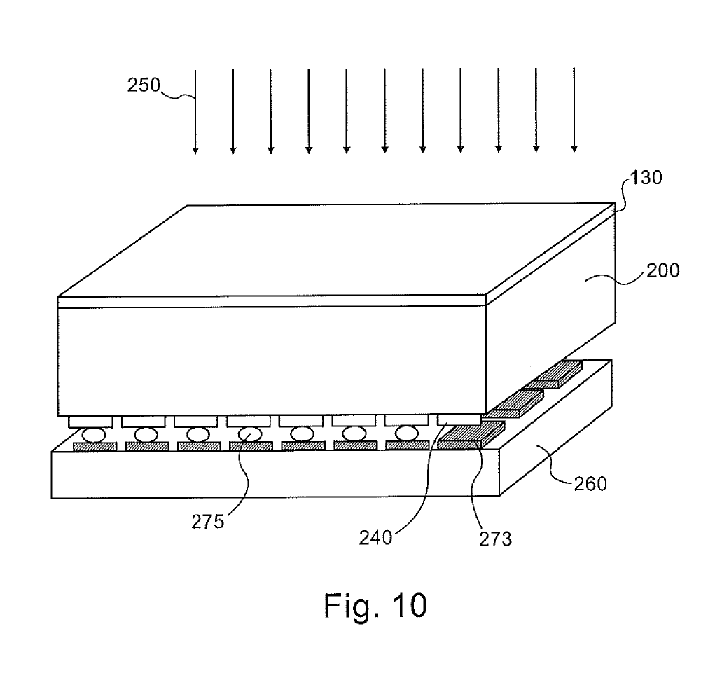

Reference is now made to FIG. 9, showing a schematic general view of a photo sensor array. The array comprises a 2D matrix of photo sensor cells. In an exemplary manner, two orthogonal pixel rows 203 and 205 are shown.

Reference is now made to FIG. 10, presenting the photo sensor array with the read-out integrated circuit. The sandwich structure 200 is provided with a GaAs based back gate layer electrode 130 which is transparent to the NIR spectral band. The radiation 250 to be detected is incident onto the sandwich structure 200. An induced response is picked up by the read-out integrated circuit 260. The circuit 260 has a matrix of contact members 270 configured to be in electric contact with the contact patches 240. Thus, an electric signal induced in each photo sensor is picked in an individual manner.

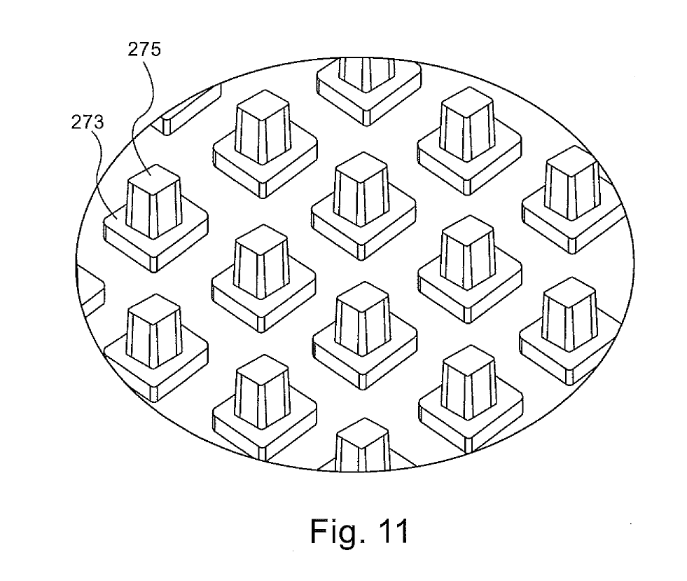

Reference is now made to FIG. 11, showing an enlarged view of contact members on the read-out integrated circuit. Specifically, each contact member includes a pad 273 carrying a contact bump 275.

1-39. (canceled)

40. A detector for detecting visible and NIR electromagnetic radiation, said detector comprising:
a. a substrate made of semi-insulating gallium arsenide (GaAs);
b. a buffer layer made of semi-insulating GaAs carried by said substrate;
c. an etch stop layer carried by said buffer layer;
d. an active layer made of low-temperature grown GaAs carried by said etch stop layer; and
e. cathode and anode electrodes based on Schottky contacts carried by said active layer;
wherein said detector comprises a back gate conductive layer made of a Si-doped GaAs layer; said back gate conductive layer is located between said buffer layer and etch stop layer.

41. The detector of claim 40, wherein at least one of the following is true:
a. said active layer is doped with an impurity selected from the group consisting of chromium, ferrum, oxygen and any combination thereof;
b. said active layer is annealed;
c. said detector comprises an AlGaAs—GaAs heterojunction structure comprising a spacer layer of undoped AlₓGa₍₁₋ₓ₎As where 0.10<x<0.90 formed on said active layer followed by a supply layer of n-type doped AlₓGa₍₁₋ₓ₎As where 0.10<x<0.90;
d. said detector comprises an AlGaAs—InGaAs—GaAs heterojunction pseudomorphic structure, further comprising an undoped InₓGa₍₁₋ₓ₎As where 0.10<x<0.90 channel layer formed on said active layer followed by a spacer layer of undoped AlₓGa₍₁₋ₓ₎As where 0.10<x<0.90 followed by a supply layer of n-type doped AlₓGa₍₁₋ₓ₎As where 0.10<x<0.90;
e. said electrodes are optically transparent in the visual and NIR spectral bands; and
f. an etch stop layer is made of AlₓGa₍₁₋ₓ₎As or InₓGa₍₁₋ₓ₎P where 0.10<x<0.90.

42. The detector of claim 41, wherein said heterojunction structures are located between said active layer and anode and cathode electrodes.

43. A detector for detecting visible and NIR electromagnetic radiation, said detector comprising:
a. a substrate made of semi-insulating gallium arsenide (GaAs);
b. a buffer layer made of semi-insulating GaAs carried by said substrate;
c. an etch stop layer carried by said buffer layer;
d. an active layer made of ion-implemented GaAs carried by said etch stop layer; and
e. cathode and anode electrode based on Schottky contacts carried by said active layer;
wherein said detector comprises a back gate conductive layer made of a Si-doped GaAs layer; said back gate conductive layer is located between said buffer layer and etch stop layer.

44. The detector of claim 43, wherein at least one of the following is true:
a. said active layer is doped with an impurity selected from the group consisting of chromium, ferrum, oxygen and any combination thereof;
b. said active layer is annealed;
c. said detector comprises an AlGaAs—GaAs heterojunction structure comprising a spacer layer of undoped AlₓGa₍₁₋ₓ₎As where 0.10<x<0.90 formed on said active layer followed by a supply layer of n-type doped AlₓGa₍₁₋ₓ₎As where 0.10<x<0.90;
d. said detector comprises an AlGaAs—InGaAs—GaAs heterojunction pseudomorphic structure, further comprising an undoped InₓGa₍₁₋ₓ₎As where 0.10<x<0.90 channel layer formed on said active layer followed by a spacer layer of undoped AlₓGa₍₁₋ₓ₎As where 0.10<x<0.90 followed by a supply layer of n-type doped AlₓGa₍₁₋ₓ₎As where 0.10<x<0.90;
e. said electrodes are optically transparent in the visual and NIR spectral bands; and
f. an etch stop layer is made of AlₓGa₍₁₋ₓ₎As or InₓGa₍₁₋ₓ₎P where 0.10<x<0.90.

45. The detector of claim 44, wherein said heterojunction structures are located between said active layer and anode and cathode electrodes.

46. An imager for imaging in the visible and NIR spectral bands, comprising:
a. a monolithically integrated array of detectors comprising
i. a shared array substrate made of semi-insulating gallium arsenide (GaAs);
ii. a shared array buffer layer made of semi insulating GaAs carried by said shared array substrate;
iii. a shared array etch stop layer carried by said shared array buffer layer;
iv. a shared array active layer made of low-temperature grown GaAs; said shared array active layer carried by said shared array etch stop layer;
v. cathode and anode electrodes based on Schottky contacts carried by said shared array active layer which individually connected to each elemental detector of said monolithically integrated array;
vi. reading means electrically connected to each elemental detector of said monolithically integrated array in an individual manner;
b. a read-out integrated circuit (ROIC) for individually interrogating each detector in said array, controlling array's operation and processing detected signals from each detectors of said array to create a combined video signal;
c. means for electrically connecting each detector and shared layers of said array to said ROIC;
wherein said imager comprises a shared array back gate layer made of a Si-doped GaAs layer; said shared array back gate conductive layer is located between said shared array buffer layer and shared array etch stop layer.

47. The imager of claim 46, wherein at least one of the following is true:
a. said shared array active layer is doped with an impurity selected from the group consisting of chromium, ferrum, oxygen and any combination thereof;
b. said shared array active layer is annealed;
c. a shared array etch stop layer is made of AlₓGa₍₁₋ₓ₎As or InₓGa₍₁₋ₓ₎P, where 0.10<x<0.90;
d. said imager comprises comprising an AlGaAs—GaAs heterojunction structure which comprises a shared array spacer layer of undoped AlₓGa₍₁₋ₓ₎As formed on said shared array active layer, where 0.10<x<0.90 followed by a shared array supply layer of n-type doped AlₓGa₍₁₋ₓ₎As where 0.10<x<0.90;
e. an AlGaAs—InGaAs—GaAs pseudomorphic heterojunction structure which comprises shared array channel layer of an undoped InₓGa₍₁₋ₓ₎As where 0.10<x<0.90 formed on said shared array active layer followed by a shared array spacer layer of undoped AlₓGa₍₁₋ₓ₎As where 0.10<x<0.90 followed by a shared array supply layer of n-type doped AlₓGa₍₁₋ₓ₎As where 0.10<x<0.90;
f. said imager is provided with imaging means; and
g. said imaging means is selected from the group consisting of a lens and a microlens array.

48. The imager of claim 47, wherein said heterojunction structures are located between said shared array active layer and anode and cathode electrodes which individually are connected to each elemental detector of said monolithically integrated array.

49. An imager for imaging in the visible and NIR spectral bands comprising:
a. a monolithically integrated array of detectors comprising:
i. a shared array substrate made of semi-insulating gallium arsenide (GaAs);
ii. a shared array buffer layer made of semi insulating GaAs carried by said shared array substrate;
iii. a shared array etch stop layer carried by said shared array buffer layer;
iv. a shared array active layer made of ion-implemented GaAs; said shared array active layer carried by said shared array etch stop layer;
v. cathode and anode based on Schottky electrodes carried by said shared array active layer which individually connected to each elemental detector of said monolithically integrated array;
vi. reading means electrically connected to each elemental detector of said monolithically integrated array in an individual manner;
b. a read-out integrated circuit (ROIC) for individually interrogating each detector in said array, controlling array's operation and processing detected signals from each detectors of said array to create a combined video signal;
c. means for electrically connecting each detector and shared layers of said array to said ROIC;
wherein said imager comprises a shared array back gate layer made of a Si-doped GaAs layer; said shared array back gate conductive layer is located between said shared array buffer layer and shared array etch stop layer.

50. The imager of claim 49, wherein at least one of the following is true:
a. said shared array active layer is doped with an impurity selected from the group consisting of chromium, ferrum, oxygen and any combination thereof;
b. said shared array active layer is annealed;
c. a shared array etch stop layer is made of AlₓGa₍₁₋ₓ₎As or InₓGa₍₁₋ₓ₎P, where 0.10<x<0.90;
d. said imager comprises comprising an AlGaAs—GaAs heterojunction structure which comprises a shared array spacer layer of undoped AlₓGa₍₁₋ₓ₎As formed on said shared array active layer, where 0.10<x<0.90 followed by a shared array supply layer of n-type doped AlₓGa₍₁₋ₓ₎As where 0.10<x<0.90;
e. an AlGaAs—InGaAs—GaAs pseudomorphic heterojunction structure which comprises shared array channel layer of an undoped InₓGa₍₁₋ₓ₎As where 0.10<x<0.90 formed on said shared array active layer followed by a shared array spacer layer of undoped AlₓGa₍₁₋ₓ₎As where 0.10<x<0.90 followed by a shared array supply layer of n-type doped AlₓGa₍₁₋ₓ₎As where 0.10<x<0.90;
f. said imager is provided with imaging means; and
g. said imaging means is selected from the group consisting of a lens and a microlens array.

51. The imager of claim 50, wherein said heterojunction structures are located between said shared array active layer and anode and cathode electrodes which individually are connected to each elemental detector of said monolithically integrated array.

52. A method of detecting electromagnetic radiation comprising the steps of:
a. providing detector for detecting visible and NIR electromagnetic radiation, said detector comprising:
i. a substrate made of semi-insulating gallium arsenide (GaAs);
ii. a buffer layer made of semi insulating GaAs and carried by said substrate;
iii. an etch stop layer carried by said buffer layer;
iv. an active layer made of low-temperature grown GaAs carried by said etch stop layer;
v. cathode and anode electrodes based on Schottky contacts carried by said active layer;
b. illuminating said detector by electromagnetic radiation; and
c. measuring change in current across said detector;
wherein said method further comprises a step applying a vertical electric field by means of a back gate conductive layer made of a Si-doped GaAs layer; said back gate conductive layer is located between said buffer layer and etch stop layer.

53. A method of detecting electromagnetic radiation comprising the steps of:
a. providing detector for detecting visible and NIR electromagnetic radiation, said detector comprising:
i. a substrate made of semi-insulating gallium arsenide (GaAs);
ii. a buffer layer made of semi insulating GaAs and carried by said substrate;
iii. an etch stop layer carried by said buffer layer;
iv. an active layer made of ion-implanted GaAs; said active layer carried by said etch stop layer;
v. cathode and anode electrodes based on Schottky contacts carried by said active layer;
b. illuminating said detector by electromagnetic radiation; and
c. measuring change in current across said detector;
wherein said method further comprises a step applying a vertical electric field by means of a back gate conductive layer made of a Si-doped GaAs; said back gate conductive layer is located between said buffer layer and etch stop layer.

54. A method of imaging in electromagnetic radiation comprising the steps of:
a. providing an imager for imaging in the visible and NIR spectral bands, said imager based on an array of detectors comprising:
i. a monolithically integrated array of detectors comprising:
1. a shared array substrate made of semi-insulating gallium arsenide (GaAs);
2. a shared array buffer layer made of semi-insulating GaAs carried by said shared array substrate;
3. a shared array etch stop layer carried by said shared array buffer layer;
4. a shared array active layer made of low-temperature grown GaAs; said shared array active layer carried by said shared array etch stop layer;
5. cathode and anode electrodes based on Schottky contacts which individually connected to each elemental detector of said monolithically integrated array;
6. reading means electrically connected to each elemental detector of said monolithically integrated array in an individual manner;
ii. a read-out integrated circuit (ROIC) for individually interrogating each detector in said array, controlling array's operation and processing the detected signals from each detectors of said array to create a combined video signal;
iii. means for electrically connecting each detector of said array to said ROIC;
b. illuminating said detector by electromagnetic radiation; and
c. measuring change in current across said cathode and anode electrodes;
wherein said method further comprises a step applying a vertical electric field by means of a shared array back gate conductive layer made of a Si-doped GaAs; said shared array back gate conductive layer is located between said shared array buffer layer and shared array etch stop layer.

55. A method of imaging in electromagnetic radiation comprising the steps of:
a. providing an imager for imaging in the visible and NIR spectral bands, said imager based on an array of detectors comprising:
i. a monolithically integrated array of detectors comprising
1. a shared array substrate made of semi-insulating gallium arsenide (GaAs);
2. a shared array buffer layer made of semi insulating GaAs carried by said shared array substrate;
3. a shared array etch stop layer carried by said shared array buffer layer;
4. a shared array active layer made of ion-implanted GaAs; said shared array active layer carried by said shared array etch stop layer;
5. cathode and anode electrodes based on Schottky contacts which individually connected to each elemental detector of said monolithically integrated array;
6. reading means electrically connected to each elemental detector of said monolithically integrated array in an individual manner;
ii. a read-out integrated circuit (ROIC) for individually interrogating each detector in said array, controlling array's operation and processing the detected signals from each detectors of said array to create a combined video signal;
iii. means for electrically connecting each detector of said array to said ROIC;
b. illuminating said detector by electromagnetic radiation; and
c. measuring change in current across said cathode and anode electrodes;
i. wherein said method further comprises a step applying a vertical electric field by means of a shared array back gate conductive layer made of a Si-doped GaAs layer; said shared array back gate conductive layer is located between said shared array buffer layer and shared array etch stop layer.
